(19) United States
(12) Patent Application Publication
(10) Pub. No.: US 2026/0013237 A1
(43) Pub. Date: Jan. 8, 2026

(54) RADIATION SENSING DEVICE

(71) Applicant: Tower Semiconductor Ltd., Migdal Haemek (IL)

(72) Inventors: Ruth Shima-Edelstein, Migdal Haemek (IL); Yakov Roizin, Afula (IL)

(73) Assignee: Tower Semiconductor Ltd., Migdal Haemek (IL)

(21) Appl. No.: 18/762,565

(22) Filed: Jul. 2, 2024

(51) Int. Cl. H01L 31/119; H01L 27/144

(52) U.S. Cl. CPC H10F 30/298; H10F 39/103; H10F 39/107

(57) ABSTRACT

A radiation sensing device, that includes a sensing region that includes a radiation sensor, and an exterior region that includes a first guard element, a field limiting region, an array of surface holes and one or more sub-surface inner spaces. The exterior region is configured to prevent breakdown of the radiation sensing device at a presence of a surface charge created due to the radiation. The array of surface holes and the sub-surface inner spaces are located between the first guard element and the field limiting region and are configured to reduce the capacitance pf the exterior region.

### BACKGROUND OF THE INVENTION

A radiation sensing device includes a radiation sensitive diode that is biased with a significant bias voltage in order to provide a reasonable signal to noise ratio. The significant bias voltage and especially the potential difference between the edge of the radiation sensing device may cause a breakdown. The radiation may charge the top surface of the radiation sending device which may increase the chances of breakdown, especially when operating in a humid environment.

There is a growing need to prevent the breakdown.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates an example of a cross sectional view of a portion of a radiation sensing device;

FIG. 2 illustrates an example of a cross sectional view of a portion of a radiation sensing device;

FIG. 3 illustrates an example of a cross sectional view of a portion of a radiation sensing device, of biasing circuits and of a measurement circuit;

FIG. 4 illustrates an example of a top view of a radiation sensing device;

FIG. 5 illustrates an example of a method; and

FIG. 6 illustrates an example of a method.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DESCRIPTION OF THE PREFERRED EMBODIMENTS

According to an embodiment there is provided a radiation sensing device that includes (i) a sensing region that includes a radiation sensor located at a surface of the radiation sensing device and is configured to sense radiation of a one or more specified wavelengths; and (ii) an exterior region that includes a first guard element, a field limiting region, an array of surface holes and one or more sub-surface inner spaces. The exterior region is located outside the sensing region and is configured to prevent breakdown of the radiation sensing device at a presence of a surface charge created due to the radiation. The first guard element surrounds the sensing region and is configured to collect leakage current from the exterior region of the radiation sensing device. The field limiting region surrounds the first guard element. The array of surface holes reaches one or more sub-surface inner spaces. The array of surface holes and the sub-surface inner spaces are located between the first guard element and the field limiting region.

The surface charge may be positive of negative—depending on the type of doping—for example negative charge when there are P+ type diodes in a N type substrate, and positive charge when there are N+ type diodes in a P type substrate. The surface charge may include charge accumulated in a passivation dielectrics and/or flowable oxide (FOX) materials.

According to an embodiment, the array of surface holes and the one or more sub-surface inner spaces provide a three dimensional solution for reducing the capacitance of the exterior region.

According to an embodiment, using a three dimensions solution instead of a two dimensional solution (that is implemented solely in the surface of the radiation sensing device)—reduces the area of the surface allocated to the reduction of the capacitance—thereby increases the area allocated for sensing the radiation—and increases the ratio between the area allocated to sensing the radiation and the area of the exterior region—that is not used for sensing the radiation.

According to an embodiment the reduction of capacitance reduced the charging of the radiation sensing device by the radiation impinging on the surface. The charge is inversely proportional to the capacitance and the voltage.

According to an embodiment the surface holes and the one or more sub-surface inner spaces maintain the mechanical properties (for example strength) of the radiation sensing device.

According to an embodiment the radiation of the one or more specified wavelengths is an ionizing radiation such as an x-ray radiation.

According to an embodiment, the radiation of the one or more specified wavelengths may be monochromatic or may exhibit multiple specified wavelengths.

According to an embodiment, the suggested exterior region also reduces leakage currents within the radiation sensing device.

According to an embodiment, the exterior region further includes a floating region located between the first guard element and the array of surface holes.

According to an embodiment, the exterior region includes multiple spaced apart floating guard regions that are located between the first guard element and the array of surface holes.

According to an embodiment, the one or more floating regions further assist in the prevention of the breakdown.

According to an embodiment, an aggregate volume of the surface holes is smaller than the aggregate volume of the one or more sub-surface inner spaces. This provides a better usage of the three dimensional capacitance reduction solution.

According to an embodiment, the one or more sub-surface inner spaces are formed by etching the exterior surface using a deep reactive ion etch (DRIE) process through surface holes.

According to an embodiment, the radiation sensor is configured to sense the radiation while being operated in a fully depletion mode. The operation in the fully depletion mode increases the sensitivity of the radiation sensing device.

According to an embodiment, radiation sensor includes a radiation sensing diode having a radiation sensing diode contact and a radiation sensing diode P+ region, the first guard element includes a first guard element contact and a first guard element P+ region, and the field limiting region includes a field limiting region contact and a field limiting region N+ region.

According to an embodiment, radiation sensor includes a radiation sensing diode having a radiation sensing diode contact and a radiation sensing diode N+ region, the first guard element includes a first guard element contact and a first guard element N+ region, and the field limiting region includes a field limiting region contact and a field limiting region P+ region.

According to an embodiment, the field limiting region ends at a side wall of the radiation sensing device.

According to an embodiment, the sensing region includes multiple radiation sensors.

According to an embodiment, the radiation sensing device may use a relatively thin passivation layer at the top of the radiation sensing device, as it uses other breakdown prevention device.

According to an embodiment, the manufacturing process of the radiation sensing device is simple and requires only a few number (even only one) additional masks (for breakdown prevention) during the manufacturing process-that may be used for forming the array of surface holes and the one or more sub-surface inner spaces.

According to an embodiment, the manufacturing process of the radiation sensing device is simple and does not require introducing additional epitaxial layers or deep etches for the breakdown prevention.

According to an embodiment, there is provided a method for sensing radiation, the method includes: (i) biasing a radiation sensor within a sensing region of a radiation sensing device; (ii) sensing, by the radiation sensor, radiation of a one or more specified wavelengths; and (iii) preventing, by an exterior region, a breakdown of the radiation sensing device at a presence of a surface charge created due to the radiation. The exterior region is located outside the sensing region and includes a first guard element, a field limiting region, an array of surface holes and one or more sub-surface inner spaces. The preventing includes collecting, by the first guard element leakage current from the exterior region.

According to an embodiment, the preventing includes reducing a capacity of the exterior region by the array of surface holes and the one or more sub-surface inner spaces.

According to an embodiment, the preventing includes virtually dividing a bias voltage applied to the sensing region by a floating region located between the first guard element and the array of surface holes.

According to an embodiment, the preventing includes virtually dividing a bias voltage applied to the sensing region by a multiple spaced apart floating guard regions located between the first guard element and the array of surface holes. The virtually division means that there is a first voltage difference between the sensing region and the first floating guard region, and these is a second voltage difference between the second floating guard region and the next floating guard region, and that there are one or more additional voltage difference between one or more consecutive floating guard regions, and yet a further voltage difference between a last floating guard region and the edge of the radiation sensing device.

According to an embodiment, an aggregate volume of the surface holes is smaller than the aggregate volume of the one or more sub-surface inner spaces.

According to an embodiment, the one or more sub-surface inner spaces are formed by etching the exterior surface using a deep reactive ion etch (DRIE) process through surface holes.

According to an embodiment, the biasing includes supplying a bias voltage to operate the radiation sensor in a fully depletion mode.

According to an embodiment, the field limiting region ends at a side wall of the radiation sensing device.

According to an embodiment, the method includes sensing the radiation by multiple radiation sensors.

According to an embodiment, there is provided a method for manufacturing a radiation sensing device, the method includes (i) forming a sensing region that includes a radiation sensor located at a surface of the radiation sensing device and is configured to sense radiation of a one or more specified wavelengths; and (ii) forming an exterior region that includes a first guard element, a field limiting region, an array of surface holes and one or more sub-surface inner spaces; wherein the exterior region is located outside the sensing region and is configured to prevent breakdown of the radiation sensing device at a presence of a surface charge created due to the radiation; wherein the first guard element surrounds the sensing region and is configured to collect leakage current from the exterior region of the radiation sensing device; wherein the field limiting region surrounds the first guard element; wherein the array of surface holes reaches one or more sub-surface inner spaces; and wherein the array of surface holes and the sub-surface inner spaces are located between the first guard element and the field limiting region.

It should be noted that the forming of (i) and the forming of (ii) can be executed in parallel to each other, in a partial overlapping manner and in any order manner. Usually, different layers and/or structures are formed in a defined order in which a given manufacturing step is preceded by one or more manufacturing steps that provide one or more prerequisites to the beginning of the given manufacturing step.

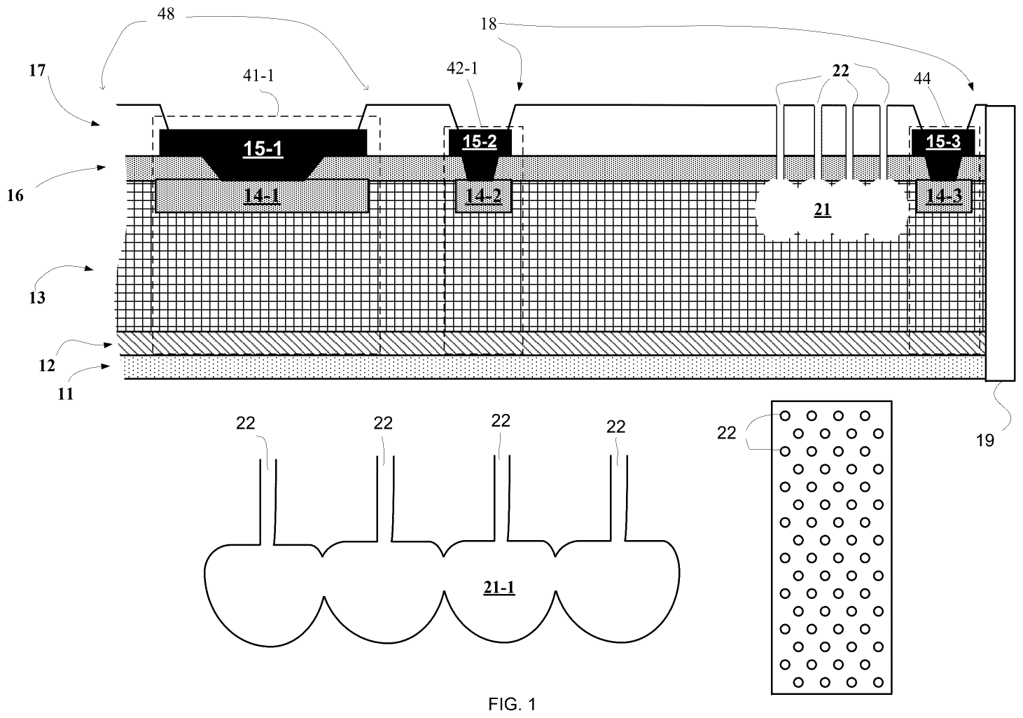

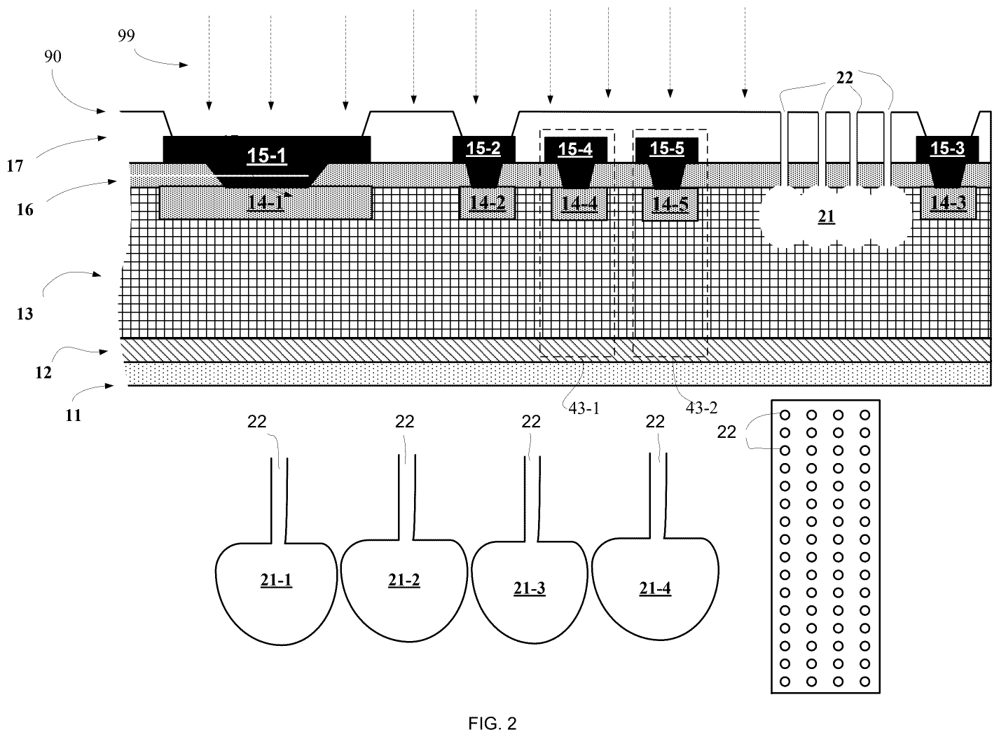

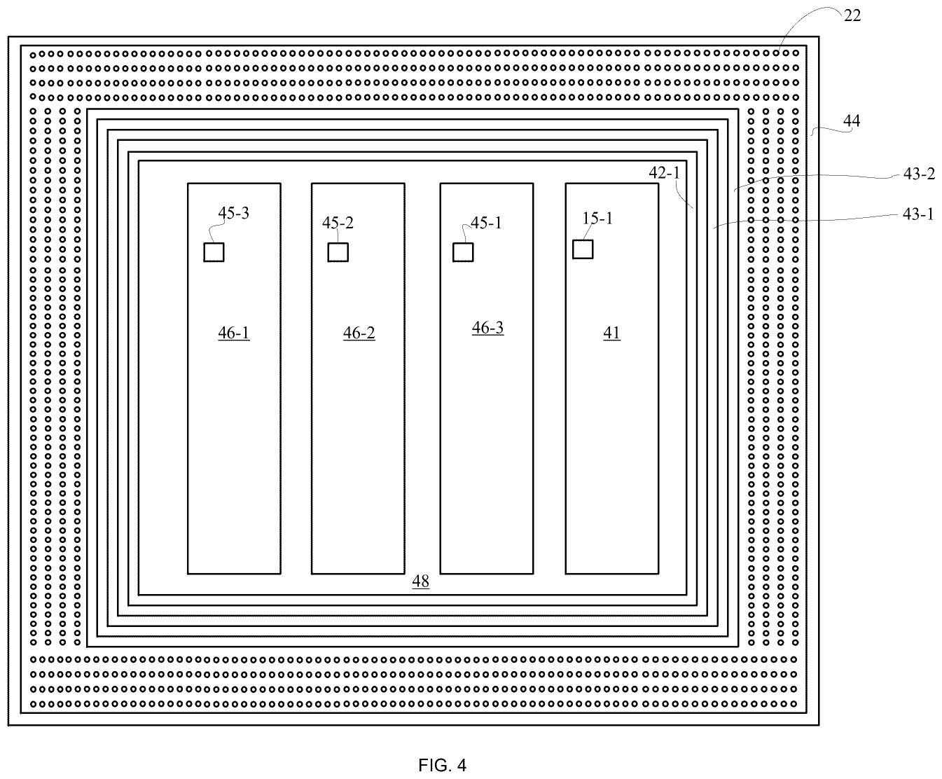

FIGS. 1-4 illustrate examples of radiation sensing devices having a top surface (denoted 90 in FIG. 2), whereas the radiation sensing devices are configured to sense radiation (denoted 99 in FIG. 2) impinging on the top surface. In some figures there is a passivation layer 17 that includes openings for exposing contacts of various components. In FIG. 4 the passivation layer was omitted for brevity of explanation.

FIG. 1 illustrates a cross section of a portion of a radiation sensing device that includes:
a. A sensing region 48 that includes a radiation sensor 41-1. The radiation sensor includes:
   i. A radiation sensor contact 15-1 that is located above a small portion of the radiation sensor.
   ii. A radiation sensing diode that includes a P+ region 14-1 and a portion of a p-type substrate 13.
   iii. A portion of the N+ layer 12. The radiation sensor is configured to sense radiation of one or more one or more specified wavelengths.
b. An exterior region 18 that includes:
   i. A first guard element 42-1 that includes first guard contact 15-2, first guard P+ region 14-2, and a portion of a p-type substrate 13.
   ii. A field limiting region 44 that includes a field limiting contact 15-3 and a field limiting N+ region 14-3.
   iii. An array of surface holes 22.
   iv. One or more sub-surface inner spaces 21. FIG. 1 illustrates a single sub-surface hole that is formed by sub-surface holes that were manufactured using different holes 22—but partially overlap so that there are no barriers between the sub-surface holes.

According to an embodiment, the portion of the N+ layer 12 is located on a metal layer 11.

According to an embodiment the radius of the holes and the spacing between adjacent holes are within a micron scale—for example between 1 and 15 microns.

The radiation sensing device is implemented on a die. A wafer that includes multiple spaced apart dies is manufactured and a singulation zone is formed between the dies—in order to allow a separation of the dies by etching.

FIG. 1 also illustrates a singulation zone 19 located to the right side of the radiation sensing device.

According to an embodiment, the exterior region is located outside the sensing region and is configured to prevent breakdown of the radiation sensing device at a presence of a surface charge created due to the radiation.

According to an embodiment, the first guard element 42-1 surrounds the sensing region and is configured to collect leakage current from the exterior region of the radiation sensing device.

According to an embodiment, the field limiting region 44 surrounds the first guard element.

According to an embodiment, the array of surface holes 22 reaches one or more sub-surface inner spaces 32.

According to an embodiment, the array of surface holes and the sub-surface inner spaces are located between the first guard element and the field limiting region.

FIG. 1 also illustrated a top view of a staggered array of surface holes 20.

FIG. 2 illustrates a cross section of a portion of a radiation sensing device that includes:
a. A sensing region 48 that includes a radiation sensor 41-1. The radiation sensor includes:
   i. A radiation sensor contact 15-1 that is located above a small portion of the radiation sensor.
   ii. A radiation sensing diode that includes a P+ region 14-1 and a portion of a p-type substrate 13.
   iii. A portion of the N+ layer 12. The radiation sensor is configured to sense radiation of one or more one or more specified wavelengths.
b. An exterior region 18 that includes:
   i. A first guard element 42-1 that includes first guard contact 15-2, first guard P+ region 14-2, and a portion of a p-type substrate 13.
   ii. A field limiting region 44 that includes a field limiting contact 15-3 and a field limiting N+ region 14-3.
   iii. Spaced apart floating guard regions (43-1, 43-2) that are not biased and include floating guard contacts (15-4 and 15-5), floating guard P+ regions (14-4 and 14-5), and portions of the p-type substrate 13. The floating guard regions are located between the first guard element and the array of surface holes
   iv. An array of surface holes 22.
   v. One or more sub-surface inner spaces 21.

According to an embodiment, the portion of the N+ layer 12 is located on a metal layer 11.

FIG. 2 also illustrates a top view of an aligned array of surface holes 20, and also illustrates sub-surface inner spaces 21-1, 21-2, 21-3 and 21-4 that are spaced apart from each other.

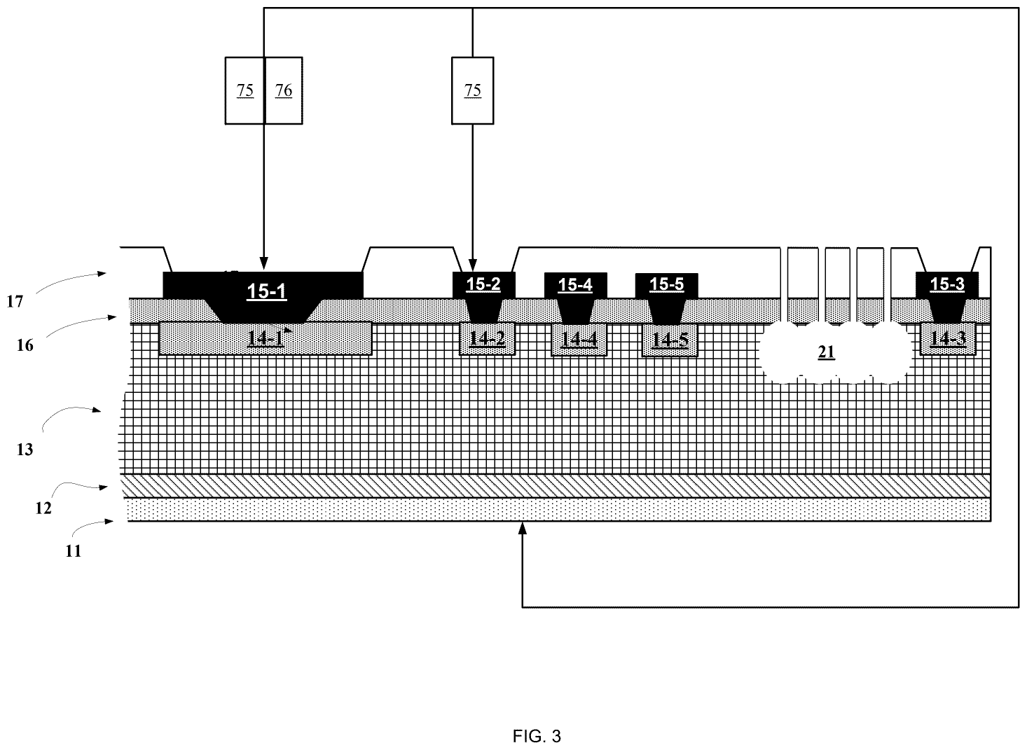

FIG. 3 illustrates an example of a cross sectional view of a portion of a radiation sensing device (of FIG. 2), of biasing circuit 75 configured to bias the radiations ensor and the first guard region by supplying voltages to the metal layer 11, the radiation sensor contact 15-1, and the first guard contact 15-2.

According to an embodiment, the sensing region includes multiple radiation sensos.

FIG. 4 illustrates an example of a top view of a radiation sensing device that include radiation sensor 41 of FIGS. 1-4 and also illustrates additional radiation sensors 46-1, 46-2 and 46-3 having their contacts 45-1, 45-2 and 45-3. There may be any number of radiation sensors and/or any shape of radiation sensors and/or any arrangement of radiation sensors within the sensing region 48.

FIG. 4 illustrates that the sensing region is surrounded by the first guard element 42-1, by the spaced apart floating guard regions (43-1, 43-2) and by the field limiting region 44.

According to an embodiment, method 600 includes forming N+ regions at the back side of an N type high resistance silicon wafer and forming N+ regions of field stops at the front side. This is followed by P+ region diffusions formation. This is followed by field oxidation in which an oxide layer (for example a 0.7-1 μm thick) oxide layer is formed over the P+ regions. Then, contact openings and metallization for forming contacts are formed. This is followed by deposition of a passivation layer and forming opening for the contact pads.

According to an embodiment the holes 22 are formed through both a field oxide layer 16 and the passivation layer 17. One additional mask is used to define the sizes of the holes. The etch process starts by etching the holes (for example holes of 2-10 um in diameter). Then, the etch is changed for silicon etching recipe similar to Bosch etch.

According to an embodiment, the etching of the holes is formed after the formation of the field oxidation.

According to an embodiment, the holes and the sub-surface inner spaces are formed by an initial anisotropic dielectric etch step through field oxide which form holes, and a second isotropic etch that forms the sub-surface inner spaces.

According to an embodiment the holes are sealed by deposition of passivation material.

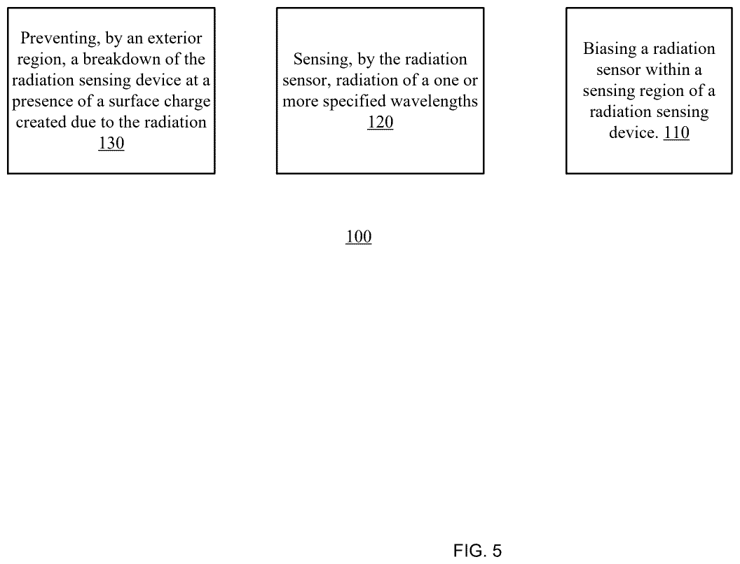

FIG. 5 illustrates an example of method 100 for sensing radiation.

According to an embodiment, method 100 includes steps 110, 120 and 130.

According to an embodiment, step 110 includes biasing a radiation sensor within a sensing region of a radiation sensing device.

According to an embodiment, step 110 includes supplying a bias voltage to operate the radiation sensor in a fully depletion mode.

According to an embodiment, step 120 includes sensing, by the radiation sensor, radiation of a one or more specified wavelengths. The sensing is a result of exposing the radiation sensing device to the radiation.

According to an embodiment step 120 is executed by more than a single radiation sensor.

According to an embodiment, step 130 includes preventing, by an exterior region, a breakdown of the radiation sensing device at a presence of a surface charge created due to the radiation.

Step 120 is executed during an execution of steps 110 and 130 while either one of step 110 and 130 may be executed while not sensing radiation—for example between one sensing iteration to another.

According to an embodiment, the exterior region is located outside the sensing region and comprises a first guard element, a field limiting region, an array of surface holes and one or more sub-surface inner spaces.

According to an embodiment, step 130 includes at least one of:
a. Collecting, by the first guard element leakage current from the exterior region.
b. Reducing a capacity of the exterior region by the array of surface holes and the one or more sub-surface inner spaces.
c. Virtually dividing a bias voltage applied to the sensing region by a floating region located between the first guard element and the array of surface holes.
d. Virtually dividing a bias voltage applied to the sensing region by a multiple spaced apart floating guard regions located between the first guard element and the array of surface holes

According to an embodiment, an aggregate volume of the surface holes is smaller than the aggregate volume of the one or more sub-surface inner spaces.

According to an embodiment, the one or more sub-surface inner spaces are formed by etching the exterior surface using a deep reactive ion etch (DRIE) process through surface holes.

According to an embodiment, the field limiting region ends at a side wall of the radiation sensing device.

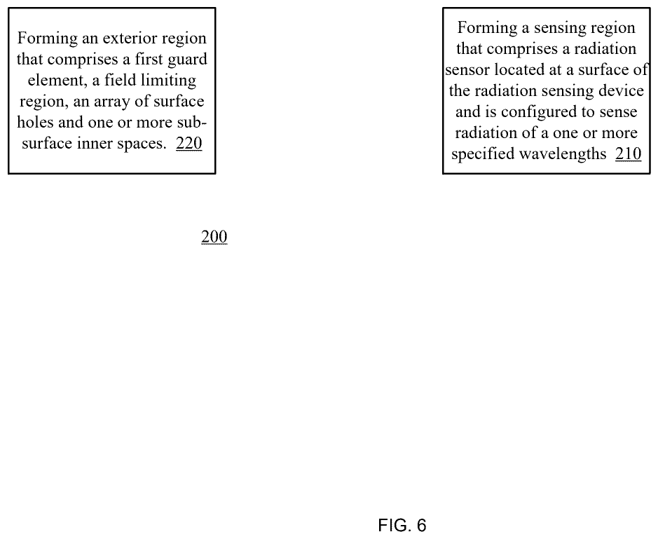

FIG. 6 illustrates an example of method 200 for manufacturing a radiation sensing device.

According to an embodiment, method 200 includes steps 210 and 220.

According to an embodiment, step 210 includes forming a sensing region that comprises a radiation sensor located at a surface of the radiation sensing device and is configured to sense radiation of a one or more specified wavelengths.

According to an embodiment, step 220 includes forming an exterior region that comprises a first guard element, a field limiting region, an array of surface holes and one or more sub-surface inner spaces. The exterior region is located outside the sensing region and is configured to prevent breakdown of the radiation sensing device at a presence of a surface charge created due to the radiation. The first guard element surrounds the sensing region and is configured to collect leakage current from the exterior region of the radiation sensing device. The field limiting region surrounds the first guard element. The array of surface holes reaches one or more sub-surface inner spaces. The array of surface holes and the sub-surface inner spaces are located between the first guard element and the field limiting region.

It should be noted that step 210 and step 220 can be executed in parallel to each other, in a partial overlapping manner and in any order manner. Usually, different layers and/or structures are formed in a defined order in which a given manufacturing step is preceded by one or more manufacturing steps that provide one or more prerequisites to the beginning of the given manufacturing step.

Any reference to any of the terms “comprise”, “comprises”, “comprising” “including”, “may include” and “includes” may be applied to any of the terms “consists”, “consisting”, “consisting essentially of”. For example-any of the rectifying circuits illustrated in any figure may include more components than those illustrated in the figure, only the components illustrated in the figure or substantially only the components illustrated in the figure.

In the foregoing detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also, for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A radiation sensing device, comprising:
a sensing region that comprises a radiation sensor located at a surface of the radiation sensing device and is configured to sense radiation of a one or more specified wavelengths; and
an exterior region that comprises a first guard element, a field limiting region, an array of surface holes and one or more sub-surface inner spaces;
wherein the exterior region is located outside the sensing region and is configured to prevent breakdown of the radiation sensing device at a presence of a surface charge created due to the radiation;
wherein the first guard element surrounds the sensing region and is configured to collect leakage current from the exterior region of the radiation sensing device;
wherein the field limiting region surrounds the first guard element; and
wherein the array of surface holes reaches one or more sub-surface inner spaces; and
wherein the array of surface holes and the sub-surface inner spaces are located between the first guard element and the field limiting region.

2. The radiation sensing device according to claim 1, wherein the exterior region further comprises a floating region located between the first guard element and the array of surface holes.

3. The radiation sensing device according to claim 1, wherein the exterior region comprises multiple spaced apart floating guard regions that are located between the first guard element and the array of surface holes.

4. The radiation sensing device according to claim 1, wherein an aggregate volume of the surface holes is smaller than the aggregate volume of the one or more sub-surface inner spaces.

5. The radiation sensing device according to claim 1, wherein the one or more sub-surface inner spaces are formed by etching the exterior surface using a deep reactive ion etch (DRIE) process through surface holes.

6. The radiation sensing device according to claim 1, wherein the radiation sensor is configured to sense the radiation while being operated in a fully depletion mode.

7. The radiation sensing device according to claim 1, wherein radiation sensor comprises a radiation sensing diode having a radiation sensing diode contact and a radiation sensing diode P+ region, the first guard element comprises a first guard element contact and a first guard element P+ region, and the field limiting region comprises a field limiting region contact and a field limiting region N+ region.

8. The radiation sensing device according to claim 1, wherein radiation sensor comprises a radiation sensing diode having a radiation sensing diode contact and a radiation sensing diode N+ region, the first guard element comprises a first guard element contact and a first guard element N+ region, and the field limiting region comprises a field limiting region contact and a field limiting region P+ region.

9. The radiation sensing device according to claim 1, wherein the field limiting region ends at a side wall of the radiation sensing device.

10. The radiation sensing device according to claim 1, wherein the sensing region comprises multiple radiation sensors.

11. A method for sensing radiation, the method comprises:
biasing a radiation sensor within a sensing region of a radiation sensing device;
sensing, by the radiation sensor, radiation of a one or more specified wavelengths;
preventing, by an exterior region, a breakdown of the radiation sensing device at a presence of a surface charge created due to the radiation;
wherein the exterior region is located outside the sensing region and comprises a first guard element, a field limiting region, an array of surface holes and one or more sub-surface inner spaces; wherein the preventing comprises collecting, by the first guard element leakage current from the exterior region.

12. The method according to claim 11, wherein the preventing comprises reducing a capacity of the exterior region by the array of surface holes and the one or more sub-surface inner spaces.

13. The method according to claim 11, wherein the preventing comprises virtually dividing a bias voltage applied to the sensing region by a floating region located between the first guard element and the array of surface holes.

14. The method according to claim 11, wherein the preventing comprises virtually dividing a bias voltage applied to the sensing region by a multiple spaced apart floating guard regions located between the first guard element and the array of surface holes

15. The method according to claim 11, wherein an aggregate volume of the surface holes is smaller than the aggregate volume of the one or more sub-surface inner spaces.

16. The method according to claim 11, wherein the one or more sub-surface inner spaces are formed by etching the exterior surface using a deep reactive ion etch (DRIE) process through surface holes.

17. The method according to claim 11, wherein the biasing comprises supplying a bias voltage to operate the radiation sensor in a fully depletion mode.

18. The method according to claim 11, wherein the field limiting region ends at a side wall of the radiation sensing device.

19. The method according to claim 11, comprising sensing the radiation by multiple radiation sensors.

20. A method for manufacturing a radiation sensing device, the method comprises:
forming a sensing region that comprises a radiation sensor located at a surface of the radiation sensing device and is configured to sense radiation of a one or more specified wavelengths; and
forming an exterior region that comprises a first guard element, a field limiting region, an array of surface holes and one or more sub-surface inner spaces; wherein the exterior region is located outside the sensing region and is configured to prevent breakdown of the radiation sensing device at a presence of a surface charge created due to the radiation; wherein the first guard element surrounds the sensing region and is configured to collect leakage current from the exterior region of the radiation sensing device; wherein the field limiting region surrounds the first guard element; wherein the array of surface holes reaches one or more sub-surface inner spaces; and wherein the array of surface holes and the sub-surface inner spaces are located between the first guard element and the field limiting region.
